(19) United States
(12) Patent Application Publication
(10) Pub. No.: US 2024/0283444 A1
(43) Pub. Date: Aug. 22, 2024

(54) Circuit And System For Reducing Current Leakage

(71) Applicant: Meta Platforms Technologies, LLC, Menlo Park, CA (US)

(72) Inventors: Umanath Ramachandra Kamath, Palo Alto, CA (US); Ali Mesgarani, Sunnyvale, CA (US); Jason Silver, Redmond, WA (US); Robert Wiser, Palo Alto, CA (US); Augusto Ronchini Ximenes, Seattle, WA (US)

(21) Appl. No.: 18/170,795

(22) Filed: Feb. 17, 2023

(51) Int. Cl. H03K 17/16

(52) U.S. Cl. CPC H03K 17/162; H01L 27/088

(57) ABSTRACT

A circuit may be configured to reduce current leakage. The circuit may include a bias generator, a charge interface, and a charge controller. The bias generator may be coupled to a first voltage source and configured to generate a first current and provide a first voltage. The charge interface may be communicatively coupled to the bias generator and configured to mirror the first current into a second current. The charge controller may be communicatively coupled to the charge interface and configured to receive the second current from the charge interface and provide a second voltage. The bias generator may be further configured to perform an ultra-low leakage switching operation in which the first voltage is switched to a third voltage while reducing a first possibility of band-band tunneling leakage at the charge interface.

### TECHNICAL FIELD

The present disclosure generally relates to circuits and systems for reducing current leakage.

### BACKGROUND

Leakage current is a current that flows from circuits to ground and/or a device casing/chassis. The leakage current may flow from an input or an output. Leakage current may occur even in circuits that are properly grounded when changes in voltage occur at different portions of the circuit. In integrated circuits, leakage current may occur between electronic elements connected to one another. In some cases, leakage current may occur even within a single electronic element.

Leakage current is a type of leakage current that may occur in transistors. A transistor comprises at least three terminals. The leakage current may occur between terminals where a first terminal partially overlaps with a second terminal in the transistor if these terminals comprise severely mismatched currents. Leakage may occur from the first terminal to the second terminal by tunneling from a first material in the first terminal to a second terminal in the second terminal. The current may deteriorate any signals meant to be transmitted between the first terminal and the second terminal.

### SUMMARY OF THE DISCLOSURE

Memory storing devices may suffer from leakage currents during idle times. Leakage currents may be currents that cause a memory storing device to lose information over time. In particular, the leakage current may cause information stored in the memory storing device to deteriorate. As current leaks from the memory storing device, the information is lost. For example, a memory storing device represented by a charged capacitor may lose a charge via a leakage current in a connection between one of its terminals. In this example, the leakage current may cause the capacitor to discharge. The unintended discharging of the capacitor via the leakage current causes the original charge in the capacitor to decrease. In this example, the charge (i.e., or a corresponding voltage value) is the information held by the capacitor and this information deteriorates over time as the leakage current discharges the capacitor.

Discharging a given pre-charged (or reset) capacitor in successive sequence by a fixed amount of reference charge may be used in sensor interfaces or data conversion applications. In these applications, a time between successive discharge events may be long.

In some embodiments, the discharge events may be unknown or uncontrolled. Any leakage current during the time may deteriorate the information stored on the capacitor while impacting a Signal-to-Noise ratio.

In one or more embodiments, band-band tunneling leakage is a type of leakage current that may occur in transistors implemented in discharging interfaces. The band-band tunneling leakage may occur between to overlapping terminals in a transistor. Leakage may occur from a first terminal to a second terminal by tunneling from a first material in the first terminal to a second terminal in the second terminal.

In some embodiments, a circuit and system described herein are configured to reduce possibilities of band-band tunneling leakage in a transistor configured to discharge a memory storing device or capacitor. The circuit and system comprise structural elements that are integrated into a practical application of reducing current leakage without making any modifications to the materials comprising the terminals of the transistor. Further, the circuit and system are integrated into a practical application of reducing current leakage at different overlapping terminals in the transistor. In this regard, the technical solutions described herein reduce a first possibility of band-band tunneling leakage between a first current terminal and a second current terminal of a transistor with three terminals. Further, the technical solutions described herein reduce a second possibility of band-band tunneling leakage between the first current terminal and the second current terminal of the transistor.

In some embodiments, depending on a transistor type, the first current terminal, the second current terminal, and the control terminal may be a drain, a source, and a gate of the transistor, respectively.

In one or more embodiments, a circuit is configured to reduce band-band tunneling leakage. The circuit may include a bias generator coupled to a first voltage source and configured to generate a first current and provide a first voltage. The circuit may include a charge interface communicatively coupled to the bias generator and configured to mirror the first current into a second current. The circuit may include a charge controller communicatively coupled to the charge interface and configured to receive the second current from the charge interface and provide a second voltage. The bias generator may be further configured to perform a first ultra-low leakage switching operation in which the first voltage is switched to a third voltage while reducing a first possibility of band-band tunneling leakage at the charge interface. The charge interface may be further configured to perform a second ultra-low leakage switching operation in which the second voltage is switched to a fourth voltage while reducing reduce a second possibility of band-band tunneling leakage at the charge interface.

In some embodiments, a system may comprise a processor configured to generate a plurality of switching operation commands comprising a pulse command and a reset command. Further, the system may comprise a circuit communicatively connected to the processor and configured to reduce band-band tunneling leakage. The circuit may include a bias generator, a charge interface, and a charge controller. The bias generator may be coupled to a first voltage source and configured to generate a first current and provide a first voltage. The charge interface may be communicatively coupled to the bias generator and configured to mirror the first current into a second current. The charge controller may be communicatively coupled to the charge interface and configured to receive the second current from the charge interface and provide a second voltage. The bias generator may be further configured to receive the pulse command out of the plurality of switching commands from the processor. Further, upon receiving the pulse command, the bias generator may be configured to perform a first ultra-low leakage switching operation in which the first voltage may be switched to a third voltage while reducing a first possibility of band-band tunneling leakage at the charge interface. The charge interface may be further configured to receive the pulse command out of the plurality of switching commands from the processor. Further, upon receiving the pulse command, the charge interface may be configured to perform a second ultra-low leakage switching operation in which the second voltage is switched to a fourth voltage while reducing reduce a second possibility of band-band tunneling leakage at the charge interface

The embodiments disclosed herein are only examples, and the scope of this disclosure is not limited to them. Particular embodiments may include all, some, or none of the components, elements, features, functions, operations, or steps of the embodiments disclosed herein. Embodiments according to the invention are in particular disclosed in the attached claims directed to a circuit, a system, a method, a storage medium, and a computer system, wherein any feature mentioned in one claim category (e.g., circuit) may be claimed in another claim category (e.g., computer system) as well. The dependencies or references back in the attached claims are chosen for formal reasons only. However any subject matter resulting from a deliberate reference back to any previous claims (i.e., in particular multiple dependencies) may be claimed as well, so that any combination of claims and the features thereof are disclosed and can be claimed regardless of the dependencies chosen in the attached claims. The subject-matter which may be claimed comprises not only the combinations of features as set out in the attached claims but also any other combination of features in the claims, wherein each feature mentioned in the claims may be combined with any other feature or combination of other features in the claims. Furthermore, any of the embodiments and features described or depicted herein may be claimed in a separate claim and/or in any combination with any embodiment or feature described or depicted herein or with any of the features of the attached claims.

### BRIEF DESCRIPTION OF THE DRAWINGS

FIG. 1 illustrates an example of a band-band tunneling leakage in accordance with one or more embodiments;

FIG. 2 is a circuit diagram illustrating an ultra-low leakage switching system comprising a pulse switch, in accordance with one or more embodiments;

FIG. 3 is a circuit diagram illustrating an ultra-low leakage switching system comprising a pair of pulse inputs, in accordance with one or more embodiments;

FIG. 4 is a circuit diagram illustrating an ultra-low leakage switching system comprising a single pulse input, in accordance with one or more embodiments;

FIG. 5 is a circuit diagram illustrating an ultra-low leakage switching system comprising a reset input and a pulse switch, in accordance with one or more embodiments;

FIG. 6 is a circuit diagram illustrating an ultra-low leakage switching system comprising a reset input and a read input, in accordance with one or more embodiments; and

FIG. 7 is a block diagram illustrating a computer system, in accordance with one or more embodiments.

### DETAILED DESCRIPTION

In one or more embodiments, leakages are caused by a gradual loss of energy from a charged capacitor of a memory storing device. A leakage current may be caused by electronic devices attached to the capacitors, such as transistors or diodes, which may conduct a small amount of current even when they are turned off. As described above, even though certain electronic devices may be turned off, the leakage current may still slowly discharges the capacitor or the memory storing device.

In this disclosure, a circuit and system are configured to reduce a possibility of current leakage in the circuit. In one or more embodiments, the circuit and system selectively modify voltage values associated with nodes connected to the memory storing device. In modifying these voltage values, the circuit and system reduce a possibility of a possibility of band-band tunneling leakage in the electronic devices neighboring the memory storing device. Band-band tunneling leakage increases power consumption and may cause complete circuit failure.

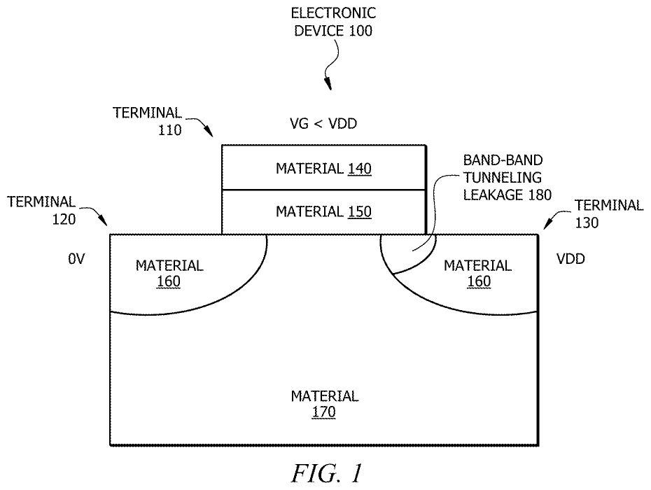

Previous technologies fail to provide efficient and reliable solutions to reduce a possibility of band-band tunneling leakage in electronic devices. Embodiments of the present disclosure and its advantages may be understood by referring to FIGS. 1-7.

### Band-Band Tunneling Leakage

FIG. 1 illustrates an example of band-band tunneling leakage 180 in an electronic device 100. In the example of FIG. 1, the electronic device 100 may be a transistor comprising three terminals 110-130. In some embodiments, a first terminal 110 may comprise a first material 140 and a second material 150. Further, a second terminal 120 and a third terminal 130 may comprise a third material 160. The three terminals 110-130 may be conjoined via a fourth material 170. As shown in FIG. 1, the band-band tunneling leakage 180 may occur in an area overlapping the first terminal 110 and the third terminal 130.

In the electronic device 100, , the band-band tunneling leakage 180 is a quantum phenomenon where charge carriers (i.e., electrons or holes) tunnel through an insulating region. The band-band tunneling leakage 180 may increase exponentially as the thickness of the insulating region decreases. The band-band tunneling leakage 180 may also occur across semiconductor junctions between P-type and N-type semiconductors with a large concentration of charge carriers (i.e., heavily doped). Other than tunneling via the gate insulator or junctions, carriers can also leak between source and drain terminals of a Metal Oxide Semiconductor (MOS) transistor. This is called subthreshold conduction (not shown). The primary source of leakage occurs inside transistors, but electrons can also leak between interconnects.

In the example of FIG. 1, for the sake of explanation, the electronic device 100 may be an Negative MOS (NMOS). In this case, the material 170 may be a positive type (i.e., p-type) substrate. Further, the first terminal 110, the second terminal 120, and the third terminal 130 may be considered to be a gate of the transistor, a source of the transistor, and a drain of the transistor. In this regard, if a negative voltage is provided at a gate terminal, positive charges may accumulate just at the oxide-substrate interface between material 160 in the first terminal 110 and material 170 in the third terminal 130. Due to the accumulated holes at the substrate, the surface behaves as a positive region more heavily doped than the substrate. This results in a thinner depletion region at the surface along the drain-substrate interface.

In one or more embodiments, the band-band tunneling leakage 180 may be a Gate Induced Drain Leakage (GIDL) that occurs where the first terminal 110 partially overlaps the third terminal 130. The GIDL may be more pronounced when drain-to-source voltage (Vds) levels are at a high potential (i.e., high voltage) and the gate-to-source voltage (Vgs) levels are at a low potential (i.e., low potential). In some embodiments, GIDL current may be due to the band-to-band tunneling process in silicon in an overlap region between the first terminal 110 and the third terminal 130. The GIDL current may increase with an increasing drain voltage (Vd) and a decreasing gate voltage (Vg). In other embodiments, the GIDL current may be proportional to a size of the overlap region. In yet other embodiments, the GIDL current may occur due to electric field potential between two terminals when the electronic device 100 is expected to be OFF.

In the example of FIG. 1, for the same Vgs, higher Vds may make the barrier steeper and facilitate the tunneling. For the same Vds, a more negative Vgs may also make the barrier steeper and facilitate the tunneling. The increasing tunneling increases the GIDL current.

### Circuit Overview

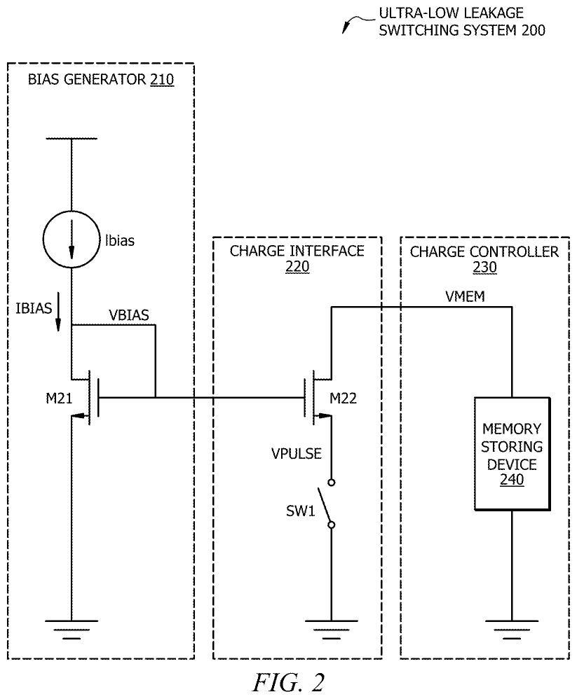

FIGS. 2-6 illustrate ultra-low leakage switching systems 200-600 in accordance with one or more embodiments. The ultra-low leakage switching systems 200-600 may be circuits comprising a bias generator 210, a charge interface 220, and a charge controller 230. As it is described in each of FIGS. 2-6, the bias generator 210 may be connected to the charge interface 220, which in turn may be connected to the charge controller 230. The bias generator 220 may be configured to generate a bias current (IBIAS) and a bias voltage (VBIAS). The charge controller 230 may include a capacitor or a memory storing device that receives or transmits a charge or information via the charge interface 220. To the charge interface 220 receives the bias current IBIAS and mirrors this current to receive or transmit charges or information. The bias current IBIAS and the bias voltage may be a current and a voltage configured to bias at least one transistor in the charge interface 220.

In one or more embodiments, the optical network 10 ultra-low leakage switching systems 200-600 reduce a possibility of the band-band tunneling leakage by dynamically modifying voltage values at the charge interface 220. In dynamically modifying one or more of these voltage values, as it will be described in more detail in reference to FIGS. 2-6

### An Ultra-Low Leakage Switching System Comprising a Pulse Switch

FIG. 2 is a circuit diagram of an ultra-low leakage switching system 200 comprising at least one pulse switch SW1 in accordance with one or more embodiments. The ultra-low leakage switching system 200 comprises the bias generator 210, the charge interface 220, and the charge controller 230. In some embodiments, the bias generator 210 comprises a current source (Ibias) connected to a voltage source (VDD) and a transistor M21. The current source Ibias comprises a first terminal connected to the voltage source VDD and a second terminal connected to a drain of the transistor M21. The drain of the transistor M21 is connected to the gate of the transistor M21 and the charge interface 220. A source of the transistor M21 is connected to ground.

In the example of FIG. 2, the charge interface 220 may include a transistor M22. A gate of the transistor M22 is connected to the gate of the transistor M21. A source of the transistor M22 is connected to a first terminal of the pulse switch SW1. A second terminal of the SW1 is connected to ground. A drain of the transistor M22 is connected to the charge controller 230. In FIG. 2, the charge controller 230 comprises a memory storing device 240 with a first terminal connected to the charge interface 220 and a second terminal connected to ground.

In one or more embodiments, the transistor M22 mirrors a current bias IBIAS generated from the bias generator 210. The current bias IBIAS may be a fixed current. In turn, the transistor M22 may provide a sink current to a node connecting the charge interface 220 and the charge controller 230 and holding a memory voltage VMEM. The switch SW1 may be switched in response to a switching command. In some embodiments, the switching command may cause the pulse switch SW1 to open or close.

The switching command may cause the pulse switch SW1 to change between a pulse voltage VPULSE and a ground voltage. In some embodiments, the voltage at the source of the transistor M22 alternates between the pulse voltage VPULSE and 0V if the pulse is in a high setting (i.e., a binary value of 1) or a low setting (i.e., a binary value of 0), respectively. In other embodiments, the pulse switch SW1 may be implemented between the gate of the transistor M22 and the gate of the transistor M21. In other embodiments, the pulse switch SW1 may be implemented between the drain of the transistor M22 and the first terminal of the memory storing device 240.

In the example of FIG. 2, the possibility of band-band tunneling leakage 180 is reduced because at least one of the terminal in the transistor M22 is pulsed. In some embodiments, the voltage difference between the gate and the drain of the transistor M22 is kept small because the gate of the transistor M22 is maintained at the bias voltage VBIAS. Further, the possibility of band-band tunneling leakage 180 is reduced because the voltage difference between the gate and the source of the transistor M22 is kept small because the gate of the transistor M22 is maintained at the bias voltage VBIAS and the source of the transistor M22 only changes between the pulse voltage VPULSE and 0V.

### An Ultra-Low Leakage Switching System Comprising a Pair of Pulse Inputs

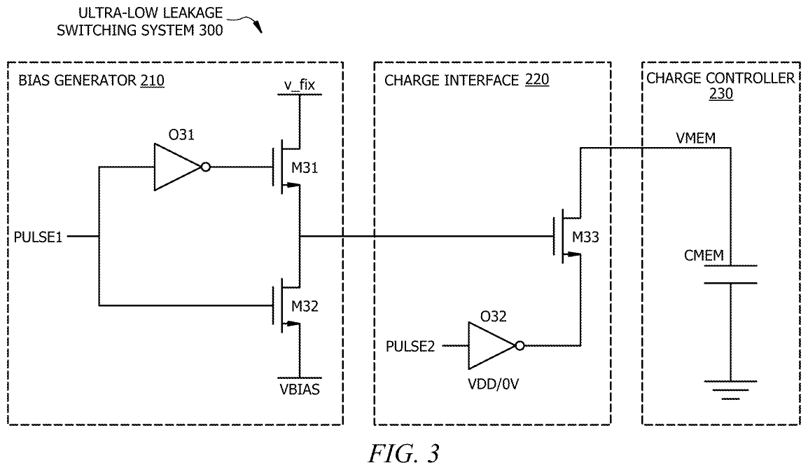

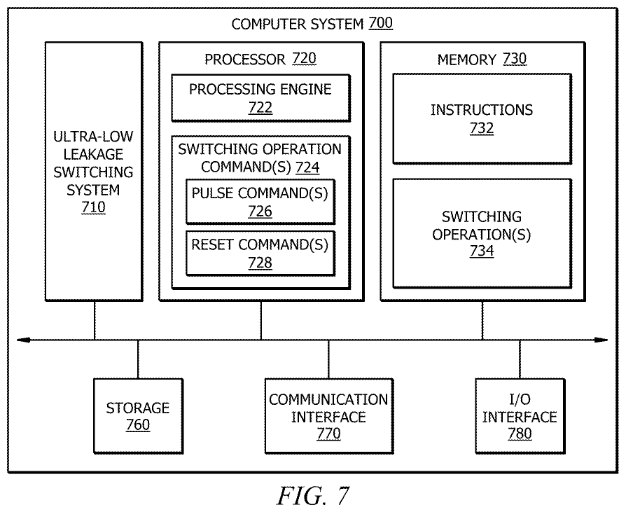

FIG. 3 is a circuit diagram of an ultra-low leakage switching system 300 comprising a pair of pulse inputs PULSE1 and PULSE2 in accordance with one or more embodiments. The ultra-low leakage switching system 300 comprises the bias generator 210, the charge interface 220, and the charge controller 230. In some embodiments, the bias generator 210 comprises a first pulse input PULSE1, an inverter O31, a transistor M31, and a transistor M32. The first pulse input PULSE1 is configured to receive a first pulse command from a processor. Pulse commands and the processor will be described in reference to FIG. 7. In FIG. 3, the first pulse input PULSE1 is connected to a first terminal of the inverter O31 and a gate of the transistor M32. A second terminal of the amplifier O31 is connected to a gate of the transistor M31. A drain of the transistor M31 is connected to a fixed reference voltage v_fix. The fixed reference voltage v_fix may be a preconfigured or predetermined voltage value that is maintained constant over a period of time. A source of the transistor M31 is connected to a drain of the transistor M32 and the charge interface 220. A source of the transistor M32 is connected to the bias voltage VBIAS. A value of the fixed voltage v_fix may be determined based in characterized data during a calibration phase of the transistor M32 in the ultra-low leakage switching system 300.

In the example of FIG. 3, the charge interface 220 may include a second pulse input PULSE2, an inverter O32, and a transistor M33. The second pulse input PULSE2 is connected to a first terminal of the inverter O32. A second terminal of the inverter O32 is connected to a source of the transmitted M33. A gate of the transistor M33 is connected to the source of the transistor M31 and the drain of the transistor M32 in the bias generator 210. A drain of the transistor M33 is connected to the charge controller 230. In FIG. 3, the charge controller 230 includes a memory capacitor CMEM with a first terminal connected to the charge interface 220 and a second terminal connected to ground.

In one or more embodiments, the transistor M31 and the transistor M32 provide the fixed voltage value v_fix or the bias voltage VBIAS to the gate of the transistor M33 based on a change in a pulse command received at the first pulse input PULSE1. In a case that the pulse command is a high setting (i.e., a binary value of 1), the inverter O31 provides a low setting (i.e., a binary value of 0) to the gate of the transistor M31. Further, the high setting may cause the transistor M32 to provide the VBIAS to the gate of the transistor M33. In turn, the transistor M33 may provide a sink current to the node connecting the charge interface 220 and the charge controller 230 and holding the memory voltage VMEM. In a case that the pulse command is a low setting, the inverter O31 provides a high setting to the gate of the transistor M31, which causes the transistor M31 to provide the fixed voltage v_fix to the gate of the transistor M33. In turn, the transistor M33 may remained closed (i.e., the gate is not saturated). In some embodiments, the transistor M33 may be opened or closed in response to the voltage received at the gate of the transistor M33.

The second input PULSE2 may be configured to receive a pulse command that causes the inverter O32 to output a value that alternates between the voltage source VDD and 0V if the pulse is in a low setting or a high setting, respectively.

In one or more embodiments, the pair of pulse inputs PULSE1 and PULSE2 may be a receive a same pulse command or different pulse commands. Specifically, the pair of pulse inputs PULSE1 and PULSE2 may receive a same high setting signal or a same low setting signal.

In the example of FIG. 3, the possibility of band-band tunneling leakage 180 is reduced because pulsing at least two of the terminal in the transistor M33 turns the transistor M33 to an OFF mode. In some embodiments, the voltage difference between the gate and the drain of the transistor M33 is kept small because the gate of the transistor M33 is maintained at the bias voltage VBIAS or the fixed voltage v_fix. Further, the possibility of band-band tunneling leakage 180 is reduced because the voltage difference between the gate and the source of the transistor M33 is kept small because the gate of the transistor M33 is maintained at the bias voltage VBIAS or the fixed voltage v_fix and the source of the transistor M33 only changes between the pulse voltage VDD and 0V.

### An Ultra-Low Leakage Switching System Comprising a Single Pulse Input

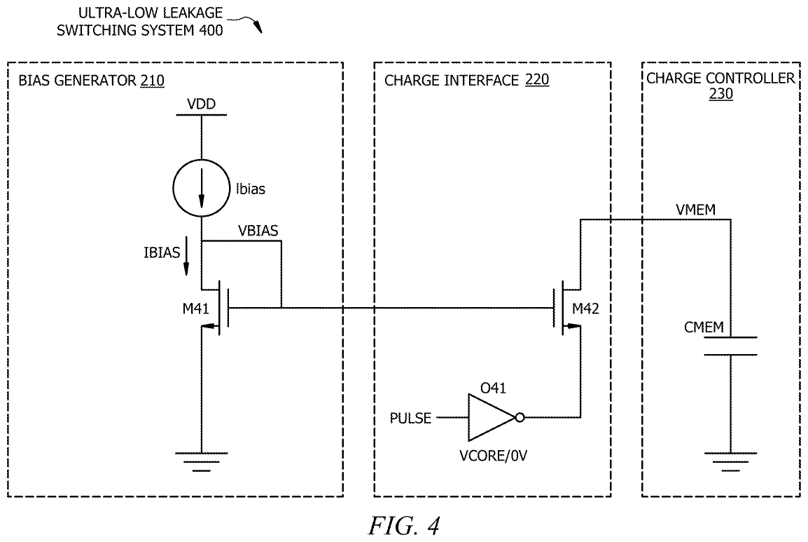

FIG. 4 is a circuit diagram of an ultra-low leakage switching system 400 comprising a single pulse input PULSE in accordance with one or more embodiments. The ultra-low leakage switching system 400 comprises the bias generator 210, the charge interface 220, and the charge controller 230. In some embodiments, the bias generator 210 comprises a current source Ibias connected to a voltage source VDD and a transistor M41. The current source Ibias comprises a first terminal connected to the voltage source VDD and a second terminal connected to a drain of the transistor M41. The drain of the transistor M41 is connected to the gate of the transistor M41 and the charge interface 220. A source of the transistor M41 is connected to ground.

In the example of FIG. 4, the charge interface 220 may include a pulse input PULSE, an inverter O41, and a transistor M42. The second pulse input PULSE is connected to a first terminal of the inverter O41. A second terminal of the inverter O41 is connected to a source of the transmitted M42. A gate of the transistor M42 is connected to the gate of the transistor M41 in the bias generator 210. A drain of the transistor M42 is connected to the charge controller 230. In FIG. 4, the charge controller 230 includes a memory capacitor CMEM with a first terminal connected to the charge interface 220 and a second terminal connected to ground.

In one or more embodiments, the transistor M42 mirrors a current bias IBIAS generated from the bias generator 210. The current bias IBIAS may be a fixed current. In turn, the transistor M42 may provide a sink current to the node connecting the charge interface 220 and the charge controller 230 and holding the memory voltage VMEM. The pulse input PULSE may be configured to receive a pulse command that causes the inverter O41 to output a value that alternates between a core voltage VCORE and 0V if the pulse command is in a low setting or a high setting, respectively.

In the example of FIG. 4, the possibility of band-band tunneling leakage 180 is reduced because the voltage difference between the gate and the source of the transistor M42 is kept small because the gate of the transistor M42 is maintained at the bias voltage VBIAS and the source of the transistor M42 only changes between the pulse voltage VCORE and 0V. In some embodiments, a voltage value of VCORE is a lower voltage than the voltage supplied by the voltage source VDD.

### An Ultra-Low Leakage Switching System Comprising a Pulse Switch and a Reset Input

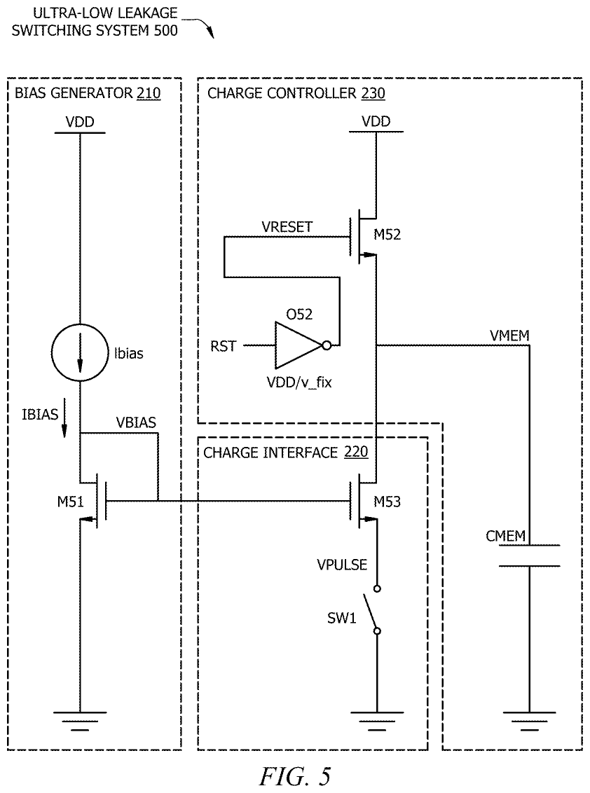

FIG. 5 is a circuit diagram of an ultra-low leakage switching system 500 comprising at least one pulse switch SW1 and a pulse reset RST in accordance with one or more embodiments. The ultra-low leakage switching system 500 comprises the bias generator 210, the charge interface 220, and the charge controller 230. In some embodiments, the bias generator 210 comprises a current source Ibias connected to a voltage source VDD and a transistor M51. The current source Ibias comprises a first terminal connected to the voltage source VDD and a second terminal connected to a drain of the transistor M51. The drain of the transistor M51 is connected to the gate of the transistor M51 and the charge interface 220. A source of the transistor M51 is connected to ground.

In the example of FIG. 5, the charge interface 220 may include a transistor M53. A gate of the transistor M53 is connected to the gate of the transistor M51. A source of the transistor M53 is connected to a first terminal of the pulse switch SW1. A second terminal of the SW1 is connected to ground. A drain of the transistor M53 is connected to the charge controller 230.

In FIG. 5, the charge controller 230 includes a memory capacitor CMEM, a transistor M52, an inverter O52, and the reset input RST. The memory capacitor CMEM may include a first terminal connected to the charge interface 220 and a second terminal connected to ground. The reset input RST is connected to a first terminal of the inverter O52. A second terminal of the inverter O52 is connected to a gate of the transistor M52. A drain of the transistor M52 is connected to the voltage source VDD. A source of the transistor M52 is connected to the first terminal of the memory capacitor CMEM and a drain of the transistor M53 of the charge interface 220.

In one or more embodiments, the transistor M53 mirrors a current bias IBIAS generated from the bias generator 210. The current bias IBIAS may be a fixed current. In turn, the transistor M53 may provide a sink current to the node connecting the charge interface 220 and the charge controller 230 and holding the memory voltage VMEM. The pulse switch SW1 may be switched in response to a switching command. In some embodiments, the switching command may cause the pulse switch SW1 to open or close.

In one or more embodiments, the transistor M52 resets a connection between the voltage source VDD and the drain of the transistor M53 based on a change in a reset command received at the reset input RST. The inverter O52 may change between the voltage source VDD and the fixed voltage v_fix if the reset command is in a low setting or a high setting, respectively. A voltage received at the gate of the transistor M52 is labeled as a reset voltage VRESET in FIG. 5. In a case that the reset command is a high setting (i.e., a binary value of 1), the inverter O52 provides a low setting (i.e., a binary value of 0) to the gate of the transistor M52. Further, the high setting may cause the transistor M52 to provide the voltage source VDD to the drain of the transistor M53.

The switching command may cause the pulse switch SW1 to change between a pulse voltage VPULSE and a ground voltage. In the example of FIG. 1, the possibility of band-band tunneling leakage 180 is reduced because the voltage at the source of the transistor M53 alternates between the pulse voltage VPULSE and 0V. In some embodiments, the pulse switch SW1 may be implemented between the gate of the transistor M51 and the gate of the transistor M53.

In the example of FIG. 5, the possibility of band-band tunneling leakage 180 is reduced because the voltage memory voltage VMEM may be reset to a predetermined voltage. This reset enabled the memory capacitor CMEM to be discharged without current leakage. Further, the possibility of band-band tunneling leakage 180 is reduced because the voltage difference between the drain and the gate of the transistor M53 is kept small because the transistor M52 is kept at the fixed voltage v_fix instead of turning the transistor M52 to an OFF state by connecting the gate of transistor M53 to 0V.

### An Ultra-Low Leakage Switching System Comprising a Reset Input and a Read Input

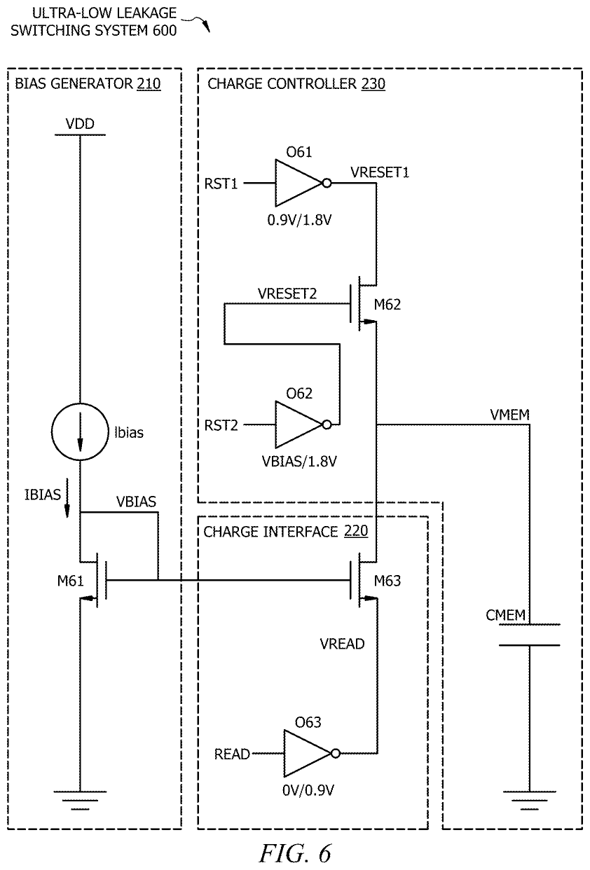

FIG. 6 is a circuit diagram of an ultra-low leakage switching system 600 comprising at least one reset input RST and a read input READ in accordance with one or more embodiments. The ultra-low leakage switching system 600 comprises the bias generator 210, the charge interface 220, and the charge controller 230. In some embodiments, the bias generator 210 includes a current source Ibias connected to the voltage source VDD and a transistor M61. The current source Ibias includes a first terminal connected to the voltage source VDD and a second terminal connected to a drain of the transistor M61. The drain of the transistor M61 is connected to the gate of the transistor M61 and the charge interface 220. A source of the transistor M61 is connected to ground.

In the example of FIG. 6, the charge interface 220 may include the read input READ, an inverter O63, and a transistor M63. The read input READ is connected to a first terminal of the inverter O63. A second terminal of the inverter O63 is connected to a source of the transmitted M63. A gate of the transistor M63 is connected to the gate of the transistor M61 in the bias generator 210. A drain of the transistor M63 is connected to the charge controller 230.

In one or more embodiments, the transistor M63 mirrors the current bias IBIAS generated from the bias generator 210. The current bias IBIAS may be a fixed current. In turn, the transistor M63 may provide a sink current to the node connecting the charge interface 220 and the charge controller 230 and holding the memory voltage VMEM. The read input READ may be configured to receive the read command that causes the inverter O63 to output a value that alternates between a first voltage (i.e., represented by 0V) and a second voltage (i.e., represented by 0.9V) if the read command is in a low setting or a high setting, respectively.

In FIG. 6, the charge controller 230 includes a memory capacitor CMEM, a transistor M62, an inverter O61, an inverter O62, a first reset input RST, and a second reset input RST. The memory capacitor CMEM may include a first terminal connected to the charge interface 220 and a second terminal connected to ground. The first reset input RST1 is connected to a first terminal of the inverter O61. A second terminal of the inverter O61 is connected to a drain of the transistor M62. The second reset input RST2 is connected to a second terminal of the inverter O62. A second terminal of the inverter O62 is connected to a gate of the transistor M62. A source of the transistor M62 is connected to the first terminal of the memory capacitor CMEM and a drain of the transistor M53 of the charge interface 220.

In one or more embodiments, the transistor M62 resets a connection between a first voltage reset VRESET 1 and the drain of the transistor M63 based on a change in a reset command received at the second reset input RST2. The inverter O61 may change between a first voltage (i.e., represented by 0.9V) and a second voltage (i.e., represented by 1.8V) if the reset command RST1 is in a low setting or a high setting, respectively. The inverter O62 may change between a first voltage (i.e., represented by VBIAS) and a second voltage (i.e., represented by 1.8V) if the reset command RST2 is in a low setting or a high setting, respectively. A voltage received at the drain of the transistor M62 is labeled as a first reset voltage VRESET1 in FIG. 6. In a case that the reset command is a high setting comprising the first voltage, the inverter O61 provides a low setting comprising the second voltage to the drain of the transistor M62. Further, in a case that the reset command is a low setting comprising the second voltage, the inverter O61 provides a high setting comprising the first voltage to the drain of the transistor M62. Further,

a voltage received at the gate of the transistor M62 is labeled as a second reset voltage VRESET2 in FIG. 6. In a case that the reset command is a high setting comprising the third voltage, the inverter O62 provides a low setting comprising the fourth voltage to the gate of the transistor M62. Further, in a case that the reset command is a low setting comprising the fourth voltage, the inverter O62 provides a high setting comprising the third voltage to the gate of the transistor M62 and causes the transistor M62 to provide the first reset voltage VRESET1 to the drain of the transistor M63.

In the example of FIG. 6, the possibility of band-band tunneling leakage 180 is reduced because the voltage memory voltage VMEM may be reset to a predetermined voltage. This reset enabled the memory capacitor CMEM to be discharged without current leakage. Further, the possibility of band-band tunneling leakage 180 is reduced because the voltage between the gate and the source of the transistor M63 is kept small and above 0V.

### Systems and Methods

FIG. 7 illustrates an example computer system 700, in accordance with one or more embodiments. This disclosure contemplates a computer system 700 taking any suitable physical form. A s example and not by way of limitation, computer system 700 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, the computer system 700 may include one or more computer systems 700; be unitary or distributed; span multiple locations; span multiple machines; span multiple data centers; or partially reside in a cloud, which may include one or more cloud components in one or more networks. Where appropriate, the one or more computer systems 700 may perform without substantial spatial or temporal limitation one or more operations of one or more methods described or illustrated herein. As an example and not by way of limitation, the one or more computer systems 700 may perform in real time or in batch mode one or more operations of one or more methods described or illustrated herein. One or more computer systems 700 may perform at different times or at different locations one or more operations of one or more methods described or illustrated herein, where appropriate.

Although this disclosure describes and illustrates a particular computer system 700 having a particular number of particular components in a particular arrangement, this disclosure contemplates any suitable computer system having any suitable number of any suitable components in any suitable arrangement.

In some embodiments, the computer system 700 comprises an ultra-low leakage switching system 710, a processor 720, a memory 730, one or more sensors 740, one or more analog-to-digital converters (ADCs), a storage 760, a communication interface 770, and an input (I)/output (O) interface 780. The ultra-low leakage switching system 710 may be one of the ultra-low leakage switching system 200-600 described in reference to FIGS. 2-6. In some embodiments, the ultra-low leakage switching system 710 may reduce leakage currents in switching operations for a sensor interface of the one or more sensors 740. In other embodiments, the ultra-low leakage switching system 710 may reduce leakage currents in switching operations for a Augmented Reality (AR) system, a Virtual Reality (VR) system, a head-mounted display (HMD), or any electric component configured to generate a simulated environment in a display (not shown).

In some embodiments, the processor 720 includes hardware for executing multiple instructions 732, such as those making up a computer program. As an example and not by way of limitation, to execute the instructions 732, the processor 720 may retrieve (or fetch) the instructions 732 from an internal register, an internal cache, the memory 730, or the storage 760; decode and execute them; and then write one or more results to an internal register, an internal cache, the memory 730, or the storage 760. In other embodiments, the processor 720 may include one or more internal caches for data, additional instructions, or addresses.

The processor 720 may include any suitable number of any suitable internal caches, where appropriate. As an example and not by way of limitation, the processor 720 may include one or more instruction caches, one or more data caches, and one or more translation lookaside buffers (TLBs). Additional instructions in the instruction caches may be copies of the instructions 732 in the memory 730 or the storage 760, and the additional instruction caches may speed up retrieval of the instructions 732 by the processor 720. Data in the data caches may be copies of data in the memory 730 or the storage 760 for the instructions 732 executed by a processing engine 722 at the processor 720 to operate on; the results of previous instructions executed at the processor 720 for access by subsequent instructions executing at the processor 720 or for writing to the memory 730 or the storage 760; or other suitable data. The data caches may speed up read or write operations by the processor 720. The TLBs may speed up virtual-address translation for the processor 720. Although this disclosure describes and illustrates a particular processor, this disclosure contemplates any suitable processor.

In one or more embodiments, the processor 720 comprises one or more switching operation commands 724. The one or more switching operation commands 724 may include the pulse commands 726, the reset commands 728, and the read commands described in reference to FIGS. 2-6. In some embodiments, the pulse commands 726, the reset commands 728, and the read commands may be a same binary signal transmission value transmitted at a same time or at different times. For example, a time t=1 ms, a first pulse command, a second pulse command, and a first reset command may be all equal to a high setting. In some embodiments, the pulse commands 726, the reset commands 728, and the read commands may be different binary signal transmission values transmitted at a same time or at different times.

In particular embodiments, the memory 730 includes main memory for storing the instructions 732 and multiple switching operations 734 for the processor 720 to execute or data for the processor 720 to operate on. As an example, and not by way of limitation, the computer system 700 may load the instructions 732 and the multiple switching operations 734 from the storage 760 or another source (such as, for example, another computer system 700) to the memory 730. The processor 720 may then load the instructions 732 from the memory 730 to an internal register or internal cache. To execute the instructions 732, the processor 720 may retrieve the instructions 732 from the internal register or internal cache and decode them. During or after execution of the instructions 732, the processor 720 may write one or more results (which may be intermediate or final results) to the internal register or internal cache. The processor 720 may then write one or more of those results to the memory 730. In other embodiments, the processor 720 executes only instructions in one or more internal registers or internal caches or in the memory 730 (as opposed to the storage 760 or elsewhere) and operates only on data in one or more internal registers or internal caches or in the memory 730 (as opposed to the storage 760 or elsewhere). One or more memory buses (which may each include an address bus and a data bus) may couple the processor 720 to the memory 730.

In particular embodiments, one or more memory management units (MMUs) reside between the processor 720 and the memory 730 and facilitate accesses to the memory 730 requested by the processor 720. In particular embodiments, the memory 730 includes random access memory (RAM). This RAM may be volatile memory, where appropriate. Where appropriate, this RAM may be dynamic RAM (DRAM) or static RAM (SRAM).

Moreover, where appropriate, this RAM may be single-ported or multi-ported RAM. This disclosure contemplates any suitable RAM. The memory 730 may include one or more memories 730, where appropriate. Although this disclosure describes and illustrates particular memory, this disclosure contemplates any suitable memory.

In particular embodiments, the storage 760 includes mass storage for data or instructions. As an example and not by way of limitation, the storage 760 may include a hard disk drive (HDD), a floppy disk drive, flash memory, an optical disc, a magneto-optical disc, magnetic tape, or a Universal Serial Bus (USB) drive or a combination of two or more of these. The storage 760 may include removable or non-removable (or fixed) media, where appropriate. The storage 760 may be internal or external to computer system 700, where appropriate. In particular embodiments, the storage 760 is non-volatile, solid-state memory. In particular embodiments, the storage 760 includes read-only memory (ROM). Where appropriate, this

ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass the storage 760 taking any suitable physical form. The storage 760 may include one or more storage control units facilitating communication between the processor 720 and the storage 760, where appropriate. Where appropriate, the storage 760 may include one or more storages 760. Although this disclosure describes and illustrates particular storage, this disclosure contemplates any suitable storage.

In some embodiments, the communication interface 770 includes hardware, software, or both providing one or more interfaces for communication (such as, for example, packet-based communication) between the computer system 700 and one or more other computer systems 700 or one or more networks. As an example and not by way of limitation, the communication interface 770 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 770 for it. As an example and not by way of limitation, the computer system 700 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, the computer system 700 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. The computer system 700 may include any suitable communication interface 770 for any of these networks, where appropriate. Although this disclosure describes and illustrates a particular communication interface 770, this disclosure contemplates any suitable communication interface.

In particular embodiments, the I/O interface 780 includes hardware, software, or both, providing one or more interfaces for communication between the computer system 700 and one or more I/O devices. The computer system 700 may include one or more of these I/O devices, where appropriate. One or more of these I/O devices may enable communication between a person and the computer system 700. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 780 for them. Where appropriate, the I/O interface 780 may include one or more device or software drivers enabling the processor 720 to drive one or more of these I/O devices. The I/O interface 780 may include one or more I/O interfaces 780, where appropriate. Although this disclosure describes and illustrates a particular I/O interface, this disclosure contemplates any suitable I/O interface.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

### Miscellaneous

As used herein, the terms “terminal”, “node”, “interconnection”, “pin” and “lead” are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (“IC”) package) and may be adapted to be coupled to at least some of the passive elements and/or the sources to form the described structure either at a time of manufacture or after a time of manufacture, for example, by an end-user and/or a third-party.

A transistor includes three terminals-a control terminal and a pair of current terminals. In the case of a field effect transistor, the control terminal is the gate, and the current terminals are the drain and source. In the case of a bipolar junction transistor, the control terminal is the base, and the current terminals are the emitter and collector.

While the use of particular transistors is described herein, other transistors (or equivalent devices) may be used instead. For example, a p-type metal-oxide-silicon field effect transistor (“MOSFET”) may be used in place of an n-type MOSFET with little or no changes to the circuit. Furthermore, other types of transistors may be used (such as bipolar junction transistors (“BJTs”)). In some embodiments, the circuits comprise of both NMOS and PMOS devices in accordance to an application preference, whereby the polarity of signals are suitably changed for PMOS compared to the ones shown for NMOS in this disclosure.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A circuit configured to reduce band-band tunneling leakage, comprising:
a bias generator coupled to a first voltage source and configured to:
generate a first current, and
provide a first voltage;
a charge interface communicatively coupled to the bias generator and configured to mirror the first current into a second current; and
a charge controller communicatively coupled to the charge interface and configured to:
receive the second current from the charge interface, and
provide a second voltage,
wherein the bias generator is further configured to perform a first ultra-low leakage switching operation in which the first voltage is switched to a third voltage while reducing a first possibility of band-band tunneling leakage at the charge interface, and
wherein the charge interface is further configured to perform a second ultra-low leakage switching operation in which the second voltage is switched to a fourth voltage while reducing reduce a second possibility of band-band tunneling leakage at the charge interface.

2. The circuit of claim 1, wherein:
the bias generator comprises a pulse input, an inverter, a first transistor, and a second transistor;
the pulse input is connected to a first terminal of the inverter and a first gate of the second transistor;
a second terminal of the inverter is connected to a second gate of the first transistor;
a first drain of the first transistor is connected to the second voltage;
a first source of the first transistor is connected to a second drain of the second transistor and the charge interface; and
a second source of the second transistor is connected to the first voltage and
the bias generator is configured to output the first voltage or the third voltage based on a signal provided via the pulse input.

3. The circuit of claim 1, wherein:
the charge interface comprises a pulse input, an inverter, and a transistor;
the pulse input is connected to a first terminal of the inverter;
a second terminal of the inverter is connected to a source of the transistor;
a drain of the transistor is connected to the charge controller;
a gate of the transistor is connected to the bias generator; and
the inverter is configured to output the second voltage or the fourth voltage based on a signal provided via the pulse input.

4. The circuit of claim 1, wherein:
the charge controller comprises a memory storing device.

5. The circuit of claim 1, wherein:
the charge controller is configured to reset a connection coupling the charge interface and the charge controller.

6. The circuit of claim 1, wherein:
the charge controller comprises a reset input, an inverter, a transistor, and a capacitor;
the reset input is connected to a first terminal of the inverter;
a second terminal of the inverter is connected to a gate of the transistor;
a drain of the transistor is connected to the first voltage source; and
a source of the transistor is connected to a first terminal of the capacitor and the charge interface.

7. The circuit of claim 1, wherein:
the charge controller comprises a reset input, a first inverter, a second inverter, a transistor, and a capacitor;
the reset input is connected to a first terminal of the first inverter and a first terminal of the second inverter;
a second terminal of the first inverter is connected to a drain of the transistor;
a second terminal of the second inverter is connected to a gate of the transistor; and
a source of the transistor is connected to a first a first terminal of the capacitor and the charge interface.

8. A circuit configured to reduce band-band tunneling leakage, comprising:
a bias generator coupled to a first voltage source and configured to:
generate a first current, and
provide a first voltage;
a charge interface communicatively coupled to the bias generator and configured to mirror the first current into a second current; and
a charge controller communicatively coupled to the charge interface and configured to:
receive the second current from the charge interface, and
provide a second voltage,
wherein the bias generator is further configured to perform a first ultra-low leakage switching operation in which the first voltage is switched to a third voltage while reducing a first possibility of band-band tunneling leakage at the charge interface.

9. The circuit of claim 8, wherein:
the bias generator comprises a pulse input, an inverter, a first transistor, and a second transistor;
the pulse input is connected to a first terminal of the inverter and a control terminal of the second transistor;
a second terminal of the inverter is connected to a control terminal of the first transistor;
a first current terminal of the first transistor is connected to the second voltage;
a second current terminal of the first transistor is connected to a third current terminal of the second transistor and the charge interface; and
a fourth current terminal of the second transistor is connected to the first voltage and
the bias generator is configured to output the first voltage or the third voltage based on a signal provided via the pulse input.

10. The circuit of claim 8, wherein the charge interface is further configured to perform a second ultra-low leakage switching operation in which the second voltage is switched to a fourth voltage while reducing reduce a second possibility of band-band tunneling leakage at the charge interface.

11. The circuit of claim 10, wherein:
the charge interface comprises a pulse input, an inverter, and a transistor;
the pulse input is connected to a first terminal of the inverter;
a second terminal of the inverter is connected to a first current terminal of the transistor;
a second current terminal of the transistor is connected to the charge controller;
a control terminal of the transistor is connected to the bias generator; and
the inverter is configured to output the second voltage or the fourth voltage based on a signal provided via the pulse input.

12. The circuit of claim 8, wherein:
the charge controller is configured to reset a connection coupling the charge interface and the charge controller.

13. The circuit of claim 8, wherein:
the charge controller comprises a reset input, an inverter, a transistor, and a capacitor;
the reset input is connected to a first terminal of the inverter;
a second terminal of the inverter is connected to a control terminal of the transistor;
a first current terminal of the transistor is connected to the first voltage source; and
a second current terminal of the transistor is connected to a first terminal of the capacitor and the charge interface.

14. The circuit of claim 8, wherein:
the charge controller comprises a reset input, a first inverter, a second inverter, a transistor, and a capacitor;
the reset input is connected to a first terminal of the first inverter and a first terminal of the second inverter;
a second terminal of the first inverter is connected to a first current terminal of the transistor;
a second terminal of the second inverter is connected to a control terminal of the transistor; and
a second current terminal of the transistor is connected to a first a first terminal of the capacitor and the charge interface.

15. A system comprising:
a processor configured to generate a plurality of switching operation commands comprising a pulse command and a reset command;
a circuit communicatively connected to the processor and configured to reduce band-band tunneling leakage, comprising:
a bias generator coupled to a first voltage source and configured to:
generate a first current, and
provide a first voltage;
a charge interface communicatively coupled to the bias generator and configured to mirror the first current into a second current; and
a charge controller communicatively coupled to the charge interface and configured to:
receive the second current from the charge interface, and
provide a second voltage,
wherein the bias generator is further configured to:
receive the pulse command out of the plurality of switching commands from the processor; and
upon receiving the pulse command, perform a first ultra-low leakage switching operation in which the first voltage is switched to a third voltage while reducing a first possibility of band-band tunneling leakage at the charge interface, and wherein the charge interface is further configured to:
receive the pulse command out of the plurality of switching commands from the processor; and
upon receiving the pulse command, perform a second ultra-low leakage switching operation in which the second voltage is switched to a fourth voltage while reducing reduce a second possibility of band-band tunneling leakage at the charge interface.

16. The system of claim 15, wherein:
the bias generator comprises a pulse input, an inverter, a first transistor, and a second transistor;
the pulse input is configured to receive the pulse command;
the pulse input is connected to a first terminal of the inverter and a gate of the second transistor;
a second terminal of the inverter is connected to a gate of the first transistor;
a drain of the first transistor is connected to the second voltage;
a source of the first transistor is connected to a drain of the second transistor and the charge interface; and
a source of the second transistor is connected to the first voltage and
the bias generator is configured to output the first voltage or the third voltage based on a signal provided via the pulse input.

17. The system of claim 15, wherein:
the charge interface comprises a pulse input, an inverter, and a transistor;
the pulse input is configured to receive the pulse command;
the pulse input is connected to a first terminal of the inverter;
a second terminal of the inverter is connected to a source of the transistor;
a drain of the transistor is connected to the charge controller;
a gate of the transistor is connected to the bias generator; and
the inverter is configured to output the second voltage or the fourth voltage based on a signal provided via the pulse input.

18. The system of claim 15, wherein:
the charge controller is configured to reset a connection coupling the charge interface and the charge controller.

19. The system of claim 15, wherein:
the charge controller comprises a reset input, an inverter, a transistor, and a capacitor;
the reset input is configured to receive the reset command;
the reset input is connected to a first terminal of the inverter;
a second terminal of the inverter is connected to a gate of the transistor;
a drain of the transistor is connected to the first voltage source; and
a source of the transistor is connected to a first terminal of the capacitor and the charge interface.

20. The system of claim 15, wherein:
the charge controller comprises a reset input, a first inverter, a second inverter, a transistor, and a capacitor;
the reset input is configured to receive the reset command;
the reset input is connected to a first terminal of the first inverter and a first terminal of the second inverter;
a second terminal of the first inverter is connected to a drain of the transistor;
a second terminal of the second inverter is connected to a gate of the transistor; and
a source of the transistor is connected to a first a first terminal of the capacitor and the charge interface.
